(19) United States
(12) Patent Application Publication
(10) Pub. No.: US 2014/0049312 A1
(43) Pub. Date: Feb. 20, 2014

(54) RF SWITCH WITH COMPLEMENTARY SWITCHING DEVICES

(71) Applicant: Chen Chih-Sheng, Taipei (TW)

(72) Inventor: Chen Chih-Sheng, Taipei (TW)

(73) Assignee: RICHWAVE TECHNOLOGY CORP., Taipei (TW)

(21) Appl. No.: 13/588,197

(22) Filed: Aug. 17, 2012

(51) Int. Cl. H03K 17/687

(52) U.S. Cl. 327/427

(57) ABSTRACT

A radio frequency (RF) switch including a common port, a first port, a second port, a first RF pathway extending between the common port and the first port, a second RF pathway extending between the common port and the second port, a first shunt path extending between the first RF pathway and ground, a second shunt path extending between the second RF pathway and ground, and a respective semiconductor switching element disposed in each of the first RF pathway, the second RF pathway, the first shunt path and the second shunt path configured to control whether the given RF pathway or shunt path is enabled or disabled at a given time, wherein a selected combination of conductivity types and control signals for the respective semiconductor switching elements are employed.

### FIELD OF THE INVENTION

The present invention relates to solid state radio frequency (RF) switches. More particularly, the present invention relates to the selection of a combination of semiconductor conductivity types for the active components of an RF switch.

### BACKGROUND OF THE INVENTION

RF switches are important building blocks in many wired and wireless communication systems. Solid state RF switches are found in many different communication devices such as cellular telephones, wireless pagers, wireless infrastructure equipment, satellite communications equipment, and cable television equipment. As is well known, the performance of solid state RF switches may be characterized by one of any number operating performance parameters including insertion loss and switch isolation. Performance parameters are often tightly coupled, and any one parameter can be emphasized in the design of RF switch components at the expense of others. Other characteristics that are important in RF switch design include ease and degree (or level) of integration of the RF switch, complexity, yield, return loss and, of course, cost of manufacture.

Still other performance characteristics associated with RF switches is the ease with which the switch may be controlled and the layout of the switch for purposes of fabrication.

### SUMMARY OF THE INVENTION

A radio frequency (RF) switch including a common port, a first port, a second port, a first RF pathway extending between the common port and the first port, a second RF pathway extending between the common port and the second port, a first shunt path extending between the first RF pathway and ground, a second shunt path extending between the second RF pathway and ground, and a semiconductor switching element disposed in each of the first RF pathway, the second RF pathway, the first shunt path and the second shunt path configured to control whether the given RF pathway or shunt path is enabled or disabled at a given time, wherein a selected combination of conductivity types and control signals for the semiconductor switching elements are employed.

In one approach, the semiconductor switching elements disposed in the first and second RF pathways are of a first conductivity type and the semiconductor switching elements disposed in the first and second shunt paths are of a second conductivity type different from the first conductivity type.

In another approach, the semiconductor switching elements disposed in the first RF pathway and the second RF pathway have complementary semiconductor conductivity types, the semiconductor switching elements disposed in the first RF pathway and the first shunt path have complementary semiconductor conductivity types, and the semiconductor switching elements disposed in the second RF pathway and the second RF shunt path have complementary semiconductor conductivity types.

In yet another approach, the semiconductor switching elements disposed in the first RF pathway and the second RF pathway have complementary semiconductor conductivity types, the semiconductor switching elements disposed in the first RF pathway and the first shunt path are of the same first conductivity type, and the semiconductor switching elements disposed in the second RF pathway and the second RF shunt path have the same second conductivity type different from the first conductivity type.

### BRIEF DESCRIPTION OF THE DRAWINGS

The present invention will become more readily apparent to those ordinarily skilled in the art after reviewing the following detailed description and accompanying drawings, in which:

FIGS. 1-4 depict respective embodiments of RF switches in accordance with the present invention.

FIG. 5 depicts a configuration of semiconductor switching elements in accordance with embodiments of the present invention.

### DETAILED DESCRIPTION OF THE PREFERRED EMBODIMENTS

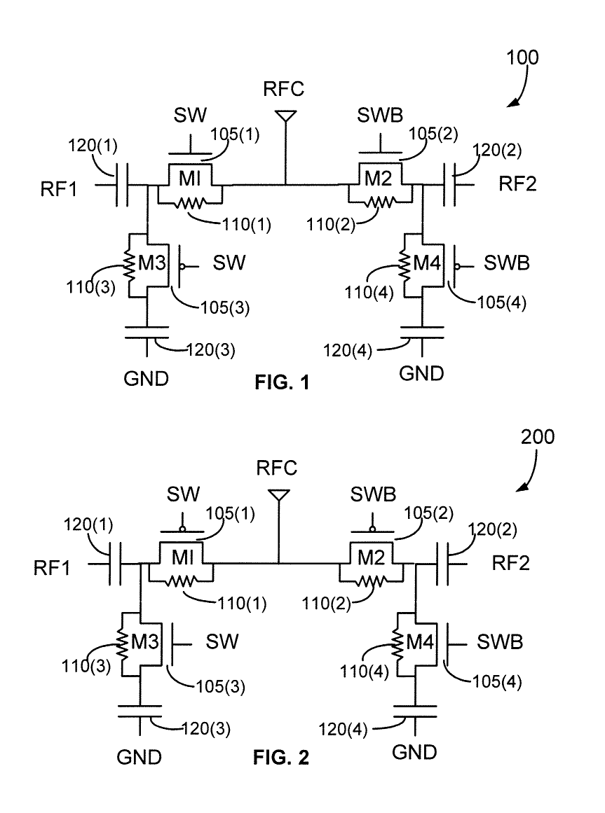

Reference is now made to FIG. 1, which depicts a first embodiment of the present invention. RF switch 100 includes an RFC (radio frequency common) port, a first port RF1 and a second port RF2. A first semiconductor switching element M1 is disposed between RFC and first port RF1, a second semiconductor switching element M2 is disposed between RFC and second port RF2, a third semiconductor switching element M3 is disposed between RF1 and ground, and a fourth semiconductor switching element M4 disposed between RF2 and ground.

A first RF pathway is defined between RFC and RF1 via M1. A second RF pathway is defined between RFC and RF2 via M2.

A first shunt path is defined between RF1 and ground via M3, and a second shunt path is defined between RF2 and ground via M4.

M1-M4 may be, for example, MOSFET devices having respective source/drain (S/D) regions (not specifically labeled in the drawings) and gate control nodes 105(1)-105(4). Although MOSFET devices are described herein as the semiconductor switching elements, the switching elements may alternatively comprise bipolar transistors among other semiconductor switching elements.

The term “source/drain region” is to be understood as one of the two regions, nodes or terminals of, e.g., a MOSFET device, that is not a gate or control terminal. Each MOSFET device will typically have two such source/drain regions and one gate or control node or terminal.

In an “enhancement mode” MOSFET, a control voltage applied to the gate terminal will induce a conducting channel to develop between a first source/drain region and a second source/drain region by drawing electrons or holes, as the case may be, into a channel region beneath the gate, and effectively connect the first source/drain region and the second source/drain region via that channel. A MOSFET can be one of two conductivity types: n-type or p-type. In an n-type MOSFET the channel is enhanced with electrons (drawn to the channel by applying a relatively positive voltage to the gate terminal). In a p-type MOSFET the channel is enhanced with holes (drawn to the channel by applying a relatively low or negative voltage to the gate terminal). Stated alternatively, in an n-type enhancement mode MOSFET, the MOSFET is turned ON when V_{GS} is greater than a threshold voltage and is otherwise OFF, and in a p-type enhancement mode MOSFET, the MOSFET is turned ON when V_{GS} is less than a threshold voltage.

Referring again to FIG. 1, RF switch 100 also comprises resistors 110(1)-110(4) connecting respective source/drain regions of each of M1-M4, and several blocking capacitors 120(1)-120(4).

Although not shown in the drawings, the source/drain regions may be biased with a DC voltage which enables RF switch 100 to better accommodate AC input signals passing through the first RF pathway or the second RF pathway.

As shown in FIG. 1, M1 and M2 are of the same conductivity type, i.e., n-type in this example, and M3 and M4 are also of the same conductivity type, but different from M1 and M2. That is, M3 and M4 are p-type devices in this example.

The gate control terminals 105(1)-105(4) are supplied with control signals SW or SWB as indicated in the figure. For purposes of discussion, SW may be considered high (e.g., 3.3. volts) or low (e.g., 0 volt), and SWB may be considered the opposite or reverse voltage of SW. That is, when SW is high, SWB will be low, and vise versa. The control signals may be the reverse of what was stated, or may also include negative voltage values depending on the supply power available in a given implementation.

FIG. 1—RF1 ON, RF2 OFF

RF switch 100 operates as follows. If it is desired to have an RF signal pass between the RFC port and RF1 via the first RF pathway, M1 is turned ON (such that an AC signal can pass therethrough) by applying high control signal SW, and M2 is turned OFF (such that an AC signal cannot pass therethrough) by applying a low control signal SWB. In the case of a MOSFET, SW may be a 3.3 volt control signal and SWB may be a 0 volt control signal.

Substantially simultaneously with the application of SW to gate 105(1) of M1 and SWB to gate 105(2) of M2, the first and second shunt paths are also controlled. Specifically, the high control signal SW is applied to gate 105(3) of M3, thus turning that p-type device OFF and disabling the first shunt path, and a low control signal SWB is applied to gate 105(4) of M4 thus turning that device ON, and thus enabling the second shunt path.

FIG. 1—RF1 OFF, RF2 ON

If it is desired to have an RF signal pass between the RFC port and RF2 via the second RF pathway, M1 is turned OFF (such that an AC signal cannot pass therethrough) by applying low control signal SW, and M2 is turned ON (such that an AC signal can pass therethrough) by applying a high control signal SWB.

Substantially simultaneously with the application of SW to gate 105(1) of M1 and SWB to gate 105(2) of M2, the first and second shunt paths are also controlled. Specifically, the low control signal SW is applied to gate 105(3) of M3, thus turning that p-type device ON and enabling the first shunt path, and a low control signal SWB is applied to gate 105(4) of M4 thus turning that device OFF, and thus disabling the second shunt path.

FIG. 1—Advantages

Notable about RF switch 100 of FIG. 1 is that the same control signal SW is used to control the first RF pathway and the first shunt path, and the same (albeit different) control signal is used to control the second RF pathway and the second shunt path. This feature may simplify routing of control signals in a given RF switch design. Likewise, because the semiconductor switching elements of both RF pathways share the same conductivity type, and the semiconductor switching elements of both shunt paths share the same conductivity type, fabrication of an RF switch consistent with the configuration shown in FIG. 1 may be simplified.

Reference is now made to FIG. 2 which shows an example of an RF switch 200 in accordance with an embodiment of the present invention. In this case, M1 and M2 have p-type conductivity, and M3 and M4 have n-type conductivity.

FIG. 2—RF1 ON, RF2 OFF

RF switch 200 operates as follows. If it is desired to have an RF signal pass between the RFC port and RF1 via the first RF pathway, M1 is turned ON (such that an AC signal can pass therethrough) by applying low control signal SW, and M2 is turned OFF (such that an AC signal cannot pass therethrough) by applying a high control signal SWB.

Substantially simultaneously with the application of SW to gate 105(1) of M1 and SWB to gate 105(2) of M2, the first and second shunt paths are also controlled. Specifically, a low control signal SW is applied to gate 105(3) of M3, thus turning that n-type device OFF and disabling the first shunt path, and a high control signal SWB is applied to gate 105(4) of M4 thus turning that device ON, and thus enabling the second shunt path.

FIG. 2—RF1 OFF, RF2 ON

If it is desired to have an RF signal pass between the RFC port and RF2 via the second RF pathway, M1 is turned OFF (such that an AC signal cannot pass therethrough) by applying a high control signal SW, and M2 is turned ON (such that an AC signal can pass therethrough) by applying a low control signal SWB.

Substantially simultaneously with the application of SW to gate 105(1) of M1 and SWB to gate 105(2) of M2, the first and second shunt paths are also controlled. Specifically, a high control signal SW is applied to gate 105(3) of M3, thus turning that n-type device ON and enabling the first shunt path, and a low control signal SWB is applied to gate 105(4) of M4 thus turning that device OFF, and thus disabling the second shunt path.

FIG. 2—Advantages

Notable about RF switch 200 of FIG. 2, like switch 1 of FIG. 1, is that the same control signal SW is used to control the first RF pathway and the first shunt path, and the same (albeit different) control signal is used to control the second RF pathway and the second shunt path. This feature may simplify routing of control signals in a given RF switch design. Likewise, because the semiconductor switching elements of both RF pathways share the same conductivity type, and the semiconductor switching elements of both shunt paths share the same conductivity type, fabrication of an RF switch consistent with the configuration shown in FIG. 2 may be simplified.

Also notable about RF switches 100 and 200 is that M1 and M3 are complementary device types and M2 and M4 are complementary device types in terms of conductivity.

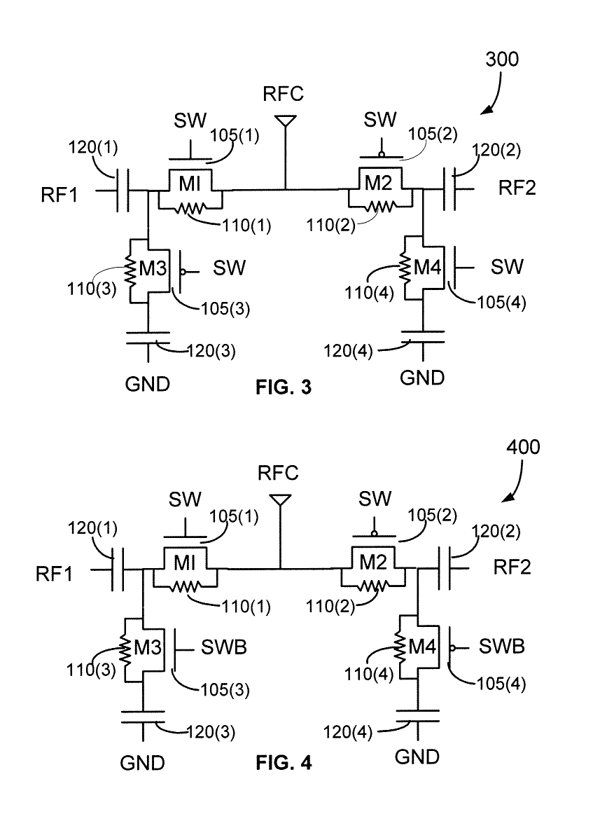

Reference is now made to FIG. 3 which shows an example of an RF switch 300 in accordance with an embodiment of the present invention. In this case, M1 and M2 have complementary conductivity types with M1 having n-type conductivity and M2 having p-type conductivity. M3 has p-type conductivity and M4 has n-type conductivity. As will be explained below, only a single control signal is needed to enable the first (or the second) RF pathway and disable the second (or the first) RF pathway.

FIG. 3—RF1 ON, RF2 OFF

RF switch 300 operates as follows. If it is desired to have an RF signal pass between the RFC port and RF1 via the first RF pathway, M1 is turned ON (such that an AC signal can pass therethrough) by applying a high control signal SW, and M2 is turned OFF (such that an AC signal cannot pass therethrough) by also applying the same high control signal SW. M2 is turned OFF since it is of p-type conductivity.

Substantially simultaneously with the application of SW to gate 105(1) of M1 and SW to gate 105(2) of M2, the first and second shunt paths are also controlled. Specifically, and once again, the same high control signal SW is applied to gate 105(3) of M3, thus turning that p-type device OFF and disabling the first shunt path, and the high control signal SW is applied to gate 105(4) of M4 thus turning that device ON, and thus enabling the second shunt path.

FIG. 3—RF1 OFF, RF2 ON

If it is desired to have an RF signal pass between the RFC port and RF2 via the second RF pathway, M1 is turned OFF (such that an AC signal cannot pass therethrough) by applying a low control signal SW, and M2 is turned ON (such that an AC signal can pass therethrough) by applying the same low control signal SW.

Substantially simultaneously with the application of SW to gate 105(1) of M1 and SW to gate 105(2) of M2, the first and second shunt paths are also controlled. Specifically, the same low control signal SW is applied to gate 105(3) of M3, thus turning that p-type device ON and enabling the first shunt path, and the low control signal SW is applied to gate 105(4) of M4 thus turning that device OFF, and thus disabling the second shunt path.

FIG. 3—Advantages

Notable about RF switch 300 of FIG. 3 is that only one control signal SW is needed to operate each and every semiconductor switching device. Thus, only one control signal needs to be generated within the switch or received from an external source to operate the switch.

Reference is now made to FIG. 4 which shows an example of an RF switch 400 in accordance with an embodiment of the present invention. In this case, M1 and M2 have complementary conductivity types with M1 having n-type conductivity and M2 having p-type conductivity (as in the embodiment shown in FIG. 3). However, here M3 has n-type conductivity and M4 has p-type conductivity.

FIG. 4—RF1 ON, RF2 OFF

RF switch 400 operates as follows. If it is desired to have an RF signal pass between the RFC port and RF1 via the first RF pathway, M1 is turned ON (such that an AC signal can pass therethrough) by applying a high control signal SW, and M2 is turned OFF (such that an AC signal cannot pass therethrough) by also applying the same high control signal SW. M2 is turned OFF since it is of p-type conductivity.

Substantially simultaneously with the application of SW to gate 105(1) of M1 and SW to gate 105(2) of M2, the first and second shunt paths are also controlled. Specifically, a low control signal SWB is applied to gate 105(3) of M3, thus turning that n-type device OFF and disabling the first shunt path, and the low control signal SWB is also applied to gate 105(4) of M4 thus turning that device ON, and thus enabling the second shunt path.

FIG. 4—RF1 OFF, RF2 ON

If it is desired to have an RF signal pass between the RFC port and RF2 via the second RF pathway, M1 is turned OFF (such that an AC signal cannot pass therethrough) by applying a low control signal SW, and M2 is turned ON (such that an AC signal can pass therethrough) by applying the same low control signal SW.

Substantially simultaneously with the application of SW to gate 105(1) of M1 and SW to gate 105(2) of M2, the first and second shunt paths are also controlled. Specifically, a high control signal SWB is applied to gate 105(3) of M3, thus turning that n-type device ON and enabling the first shunt path, and the same high control signal SWB is applied to gate 105(4) of M4 thus turning that device OFF, and thus disabling the second shunt path.

FIG. 4—Advantages

Notable about RF switch 400 of FIG. 4 is that the same control signal is used to control the first RF pathway and the second RF pathway, and another same control signal is used to control the first shunt path and the second shunt path. These features may simplify routing of control signals in a given RF switch design.

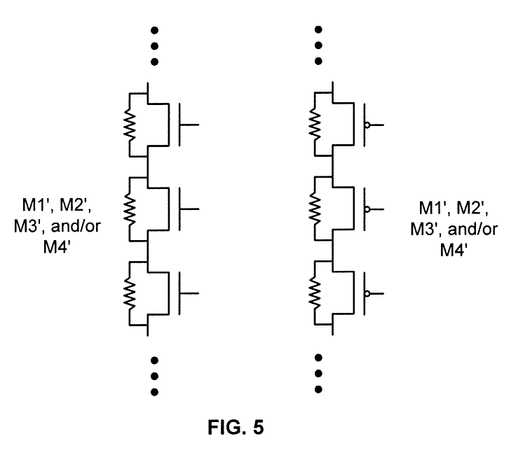

It is noted that any one of the semiconductor switching elements may be replaced with a plurality of semiconductor switching devices (typically of the same conductivity type) connected in series with one another, sometimes referred to as a “stacked” configuration. FIG. 5 shows such a configuration for M1′, M2′, M3′ or M4′, i.e., stacked version of M1, M2, M3 and/or M4.

Furthermore, while embodiments of the present invention have been described with only one RF pathway enabled at a time, those skilled in the art will appreciate that each of the RF switch configurations described herein can also be operated such that both RF pathways are enabled or disabled at the same time.

Further still, embodiments of the present invention may be embodied in an electronic device that is capable of transmitting and receiving data. The electronic device might be a wireless transceiver such as a mobile telephone that shares a common transmit and receive antenna. Such an antenna might be in electrical communication with the RFC port of the switch 100, 200, 300 or 400. RF1 might then be connected to a transmission side of the transceiver and RF2 might be connected to a receive side of the transceiver. Accordingly, the first RF pathway might carry RF energy being transmitted from the wireless transceiver through the switch, and the second RF pathway might carry RF energy received at the RFC port.

While the invention has been described in terms of what is presently considered to be the most practical and preferred embodiments, it is to be understood that the invention needs not to be limited to the above embodiments. On the contrary, it is intended to cover various modifications and similar arrangements included within the spirit and scope of the appended claims which are to be accorded with the broadest interpretation so as to encompass all such modifications and similar structures.

1. A radio frequency (RF) switch, comprising:
a common port;
a first port;
a second port;
a first RF pathway extending between the common port and the first port;
a second RF pathway extending between the common port and the second port;
a first shunt path extending between the first RF pathway and ground;
a second shunt path extending between the second RF pathway and ground; and
a respective semiconductor switching element disposed in each of the first RF pathway, the second RF pathway, the first shunt path and the second shunt path configured to control whether the given RF pathway or shunt path is enabled or disabled at a given time,
wherein the respective semiconductor switching elements disposed in the first and second RF pathways are of a first conductivity type and the respective semiconductor switching elements disposed in the first and second shunt paths are of a second conductivity type different from the first conductivity type.

2. The RF switch of claim 1, wherein the first conductivity type is n-type and the second conductivity type is p-type.

3. The RF switch of claim 1, wherein the first conductivity type is p-type and the second conductivity type is n-type.

4. The RF switch of claim 1, wherein a respective plurality of semiconductor switching elements are disposed in each of the first RF pathway, the second RF pathway, the first shunt path and the second shunt path, and function as a single switching device.

5. The RF switch of claim 1, wherein the respective semiconductor switching elements are field effect transistors.

6. The RF switch of claim 1, wherein respective control nodes of the respective semiconductor switching elements in the first RF pathway and the first shunt path are configured to receive a first control signal.

7. The RF switch of claim 6, wherein respective control nodes of the respective semiconductor switching elements in the second RF pathway and the second shunt path are configured to receive a second control signal, different from the first control signal.

8. (canceled)

9. The RF switch of claim 1, further comprising a first capacitor disposed between the respective semiconductor switching element in the first RF pathway and the first port, wherein one end of the first shunt path is coupled to a node that is common to the first capacitor and the respective semiconductor switching element in the first RF pathway; and
a second capacitor disposed between the respective semiconductor switching element in the second RF pathway and the second port, wherein one end of the second shunt path is coupled to a node that is common to the second capacitor and the respective semiconductor switching element in the second RF pathway.

10. The RF switch of claim 1, wherein the first RF pathway is an RF transmit pathway and the second RF pathway is an RF receive pathway.

11. A radio frequency (RF) switch, comprising:
a common port;
a first port;
a second port;
a first RF pathway extending between the common port and the first port;
a second RF pathway extending between the common port and the second port;
a first shunt path extending between the first RF pathway and ground;
a second shunt path extending between the second RF pathway and ground; and
a respective semiconductor switching element disposed in each of the first RF pathway, the second RF pathway, the first shunt path and the second shunt path configured to control whether the given RF pathway or shunt path is enabled or disabled at a given time,
wherein the respective semiconductor switching elements disposed in the first RF pathway and the second RF pathway have complementary semiconductor conductivity types, the respective semiconductor switching elements disposed in the first RF pathway and the first shunt path have complementary semiconductor conductivity types, and the respective semiconductor switching elements disposed in the second RF pathway and the second RF shunt path have complementary semiconductor conductivity types, and
wherein respective control nodes of the respective semiconductor switching elements in the first RF pathway, the second RF pathway, the first shunt path and the second shunt path are configured to receive a same control signal.

12. The RF switch of claim 11, wherein a respective plurality of semiconductor switching elements are disposed in each of the first RF pathway, the second RF pathway, the first shunt path and the second shunt path, and function as a single switching device.

13. The RF switch of claim 11, wherein the respective semiconductor switching elements are field effect transistors.

14. (canceled)

15. The RF switch of claim 11, wherein the respective semiconductor switching elements in the first RF pathway and the second shunt path are of a first conductivity type, and the respective semiconductor switching elements in the second RF pathway and the first shunt path are of a second conductivity type different from the first conductivity type.

16. A radio frequency (RF) switch, comprising:
a common port;
a first port;
a second port;
a first RF pathway extending between the common port and the first port;
a second RF pathway extending between the common port and the second port;
a first shunt path extending between the first RF pathway and ground;
a second shunt path extending between the second RF pathway and ground; and
a respective semiconductor switching element disposed in each of the first RF pathway, the second RF pathway, the first shunt path and the second shunt path configured to control whether the given RF pathway or shunt path is enabled or disabled at a given time,
wherein the respective semiconductor switching elements disposed in the first RF pathway and the second RF pathway have complementary semiconductor conductivity types, the respective semiconductor switching elements disposed in the first RF pathway and the first shunt path are of the same first conductivity type, and the respective semiconductor switching elements disposed in the second RF pathway and the second RF shunt path have the same second conductivity type different from the first conductivity type.

17. The RF switch of claim 16, wherein a respective plurality of semiconductor switching elements are disposed in each of the first RF pathway, the second RF pathway, the first shunt path and the second shunt path, and function as a single switching device.

18. The RF switch of claim 16, wherein the respective semiconductor switching elements are field effect transistors.

19. The RF switch of claim 16, wherein respective control nodes of the respective semiconductor switching elements in the first RF pathway and the second RF pathway are configured to receive a same first control signal, and the first shunt path and the second shunt path are configured to receive a same second control signal different from the first control signal.
